(19) United States
(12) Patent Application Publication
(10) Pub. No.: US 2016/0083865 A1
(43) Pub. Date: Mar. 24, 2016

(54) METHOD FOR MANUFACTURING SILICON CARBIDE SINGLE CRYSTAL

(71) Applicant: SUMITOMO ELECTRIC INDUSTRIES, LTD., Osaka (JP)

(72) Inventors: Takashi SAKURADA, Itami-shi (JP); Tomohiro KAWASE, Itami-shi (JP); Tsutomu HORI, Itami-shi (JP); Sho SASAKI, Itami-shi (JP)

(21) Appl. No.: 14/828,807

(22) Filed: Aug. 18, 2015

(30) Foreign Application Priority Data
Sep. 24, 2014 (JP) 2014-194088
Apr. 23, 2015 (JP) 2015-088543

(51) Int. Cl. C30B 23/06; C30B 33/02

(52) U.S. Cl. CPC C30B 23/063; C30B 33/02

(57) ABSTRACT

After growing a silicon carbide single crystal, silicon carbide single crystal is cooled. The step of growing silicon carbide single crystal includes a step of growing silicon carbide single crystal while maintaining the temperature of a second main surface of a base opposite to a first main surface to be lower than the temperature of a surface of silicon carbide single crystal facing a silicon carbide source material. In the step of cooling silicon carbide single crystal, silicon carbide single crystal is cooled while maintaining the temperature of second main surface of base to be not less than the temperature of surface of silicon carbide single crystal.

### BACKGROUND OF THE INVENTION

1. Field of the Invention

The present disclosure relates to a method for manufacturing a silicon carbide single crystal.

2. Description of the Background Art

In recent years, in order to achieve high breakdown voltage, low loss, and the like in a semiconductor device, silicon carbide has begun to be adopted as a material for the semiconductor device.

A sublimation method is exemplified as one of methods for manufacturing silicon carbide single crystals. For example, Japanese Patent Laying-Open No. 2009-120419 describes a method for manufacturing a silicon carbide single crystal by means of the sublimation method using a crucible made of graphite.

### SUMMARY OF THE INVENTION

A method for manufacturing a silicon carbide single crystal according to the present disclosure includes the following steps. A silicon carbide source material and a seed crystal are prepared, the silicon carbide source material being provided in an accommodation unit, the seed crystal being provided to face the silicon carbide source material, the seed crystal being fixed to a first main surface of a base. A silicon carbide single crystal is grown on the seed crystal by sublimating the silicon carbide source material. The silicon carbide single crystal is cooled after growing the silicon carbide single crystal. The step of growing the silicon carbide single crystal includes a step of growing the silicon carbide single crystal while maintaining a temperature of a second main surface of the base opposite to the first main surface to be lower than a temperature of a surface of the silicon carbide single crystal facing the silicon carbide source material. In the step of cooling the silicon carbide single crystal, the silicon carbide single crystal is cooled while maintaining the temperature of the second main surface of the base to be not less than the temperature of the surface of the silicon carbide single crystal.

### BRIEF DESCRIPTION OF THE DRAWINGS

FIG. 1 is a schematic cross sectional view schematically showing a first step of a method for manufacturing a silicon carbide single crystal in one embodiment.

FIG. 2 shows a schematic cross sectional view (left side) schematically showing a second step of the method for manufacturing the silicon carbide single crystal in the embodiment, and shows a temperature distribution (right side).

FIG. 3 shows a schematic cross sectional view (left side) schematically showing a third step of the method for manufacturing the silicon carbide single crystal in the embodiment, and shows a temperature distribution (right side).

FIG. 4 shows a first example of time dependency of temperature of each of a surface of the silicon carbide single crystal and a second main surface of a base 2 in the second step of the method for manufacturing the silicon carbide single crystal in the embodiment.

FIG. 5 shows time dependency of a pressure in an accommodation unit in the second step of the method for manufacturing the silicon carbide single crystal in the embodiment.

FIG. 6 shows a second example of the time dependency of the temperature of each of the surface of the silicon carbide single crystal and the second main surface of base 2 in the second step of the method for manufacturing the silicon carbide single crystal in the embodiment.

FIG. 7 shows a third example of the time dependency of the temperature of each of the surface of the silicon carbide single crystal and the second main surface of base 2 in the second step of the method for manufacturing the silicon carbide single crystal in the embodiment.

FIG. 8 shows a fourth example of the time dependency of the temperature of each of the surface of the silicon carbide single crystal and the second main surface of base 2 in the second step of the method for manufacturing the silicon carbide single crystal in the embodiment.

FIG. 9 shows a fifth example of the time dependency of the temperature of each of the surface of the silicon carbide single crystal and the second main surface of base 2 in the second step of the method for manufacturing the silicon carbide single crystal in the embodiment.

### DETAILED DESCRIPTION OF THE INVENTION

### Description of the Embodiment

The following describes embodiments with reference to figures. It should be noted that in the below-mentioned figures, the same or corresponding portions are given the same reference characters and are not described repeatedly. Regarding crystallographic indications in the present specification, an individual orientation is represented by [ ], a group orientation is represented by < >, and an individual plane is represented by ( ) and a group plane is represented by { }. In addition, a negative index is supposed to be crystallographically indicated by putting “-” (bar) above a numeral, but is indicated by putting the negative sign before the numeral in the present specification.

It is an object of the present disclosure to provide a method for manufacturing a silicon carbide single crystal so as to achieve suppression of introduction or propagation of crystal defects.

As a result of diligent study on a cause of introduction or propagation of crystal defects in a silicon carbide single crystal, the inventors have obtained the following knowledge.

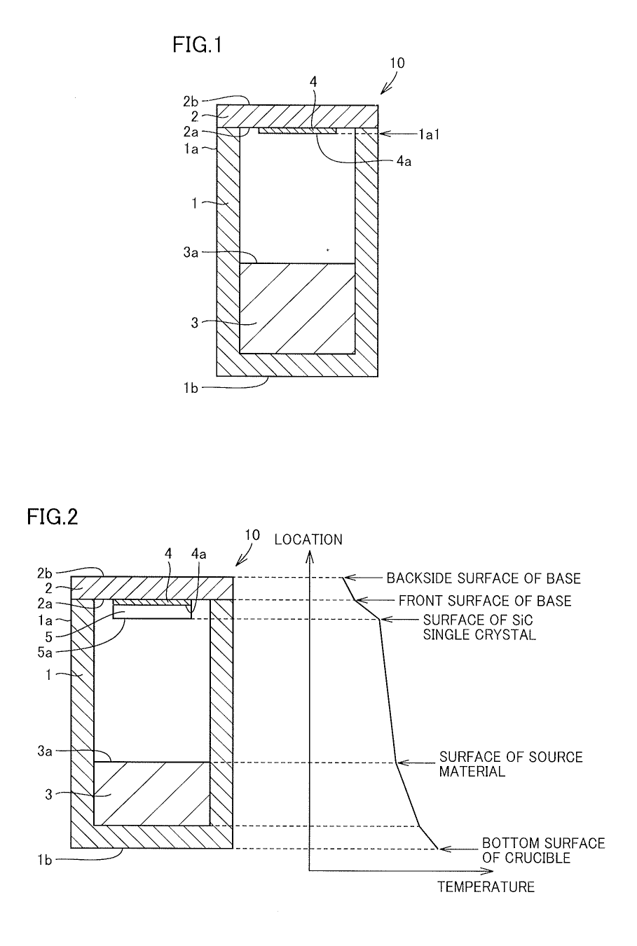

Crystal growth of a silicon carbide single crystal is performed in accordance with the sublimation method in the following manner. As shown in FIG. 1, a silicon carbide source material 3 is disposed in an accommodation unit 1. A base 2 is disposed on the upper side of accommodation unit 1 to close the opening of accommodation unit 1. A seed crystal 4 is attached to a surface 2a of base 2 to face a surface 3a of silicon carbide source material 3. A heat source (not shown) is disposed, for example, around accommodation unit 1 and is configured to be capable of adjusting the temperature of each of accommodation unit 1 and base 2 to a desired temperature. In the step of growing the silicon carbide single crystal, a temperature gradient is provided such that the temperature becomes lower in a direction from silicon carbide source material 3 toward seed crystal 4. Accordingly, when silicon carbide source material 3 is heated by the heat source to sublime, the sublimated silicon carbide is recrystallized on a surface 4a of seed crystal 4. In the manner described above, silicon carbide single crystal 5 is grown on surface 4a of seed crystal 4 (see FIG. 2).

After completion of the step of growing silicon carbide single crystal 5, the heat source is powered off to cool silicon carbide single crystal 5 thus grown. Just before powering off the heat source, the temperature of backside surface 2b of base 2 is lower than the temperature of surface 5a of silicon carbide single crystal 5 (see FIG. 2).

When the heating is stopped in this state to start cooling of silicon carbide single crystal 5, the temperature of backside surface 2b of base 2 is decreased while being maintained to be lower than the temperature of silicon carbide single crystal 5. Base 2 is composed of carbon, for example. Carbon has a thermal expansion coefficient larger than the thermal expansion coefficient of silicon carbide. Hence, when the thermal shrinkage amount of base 2 becomes larger than the thermal shrinkage amount of silicon carbide single crystal 5 during the cooling of silicon carbide single crystal 5, thermal stress is caused in silicon carbide single crystal 5.

If the thermal stress is caused in silicon carbide single crystal 5 at a relatively high temperature (for example, not less than 1000° C.), crystal defects, such as dislocations, may be introduced into silicon carbide single crystal 5 or crystal defects existing in silicon carbide single crystal 5 may be propagated in silicon carbide single crystal 5. Meanwhile, if the thermal stress is caused in silicon carbide single crystal 5 at a relatively low temperature (for example, not less than 500° C. and less than 1000° C.), a crack may be generated in silicon carbide single crystal 5 or silicon carbide single crystal 5 may be fractured. These phenomena take place more significantly in the outer circumference portion of silicon carbide single crystal 5 and take place more significantly when silicon carbide single crystal 5 has a large diameter. Particularly, when a difference in thermal expansion coefficient is large between the material of base 2 and the silicon carbide single crystal, a difference in thermal shrinkage amount between base 2 and the silicon carbide single crystal becomes more significant.

As a result of diligent study, the inventors arrived at cooling silicon carbide single crystal 5 while maintaining the temperature of backside surface 2b of base 2 to be not less than the temperature of surface 5a of silicon carbide single crystal 5 in the step of cooling silicon carbide single crystal 5 after completion of the growth of silicon carbide single crystal 5. Accordingly, silicon carbide single crystal 5 can be cooled while maintaining the thermal shrinkage amount of base 2 as large as the thermal shrinkage amount of silicon carbide single crystal 5. As a result, thermal stress in silicon carbide single crystal 5 during the cooling of silicon carbide single crystal 5 can be reduced, thereby suppressing introduction or propagation of crystal defects. Particularly, when the difference in thermal expansion coefficient between the material of base 2 and silicon carbide single crystal 5 is large, the thermal stress in silicon carbide single crystal 5 can be reduced further.

(1) A method for manufacturing a silicon carbide single crystal in the present disclosure includes the following steps. A silicon carbide source material 3 and a seed crystal 4 are prepared, silicon carbide source material 3 being provided in an accommodation unit 1, seed crystal 4 being provided to face silicon carbide source material 3, seed crystal 4 being fixed to a first main surface 2a of a base 2. A silicon carbide single crystal 5 is grown on seed crystal 4 by sublimating silicon carbide source material 3. Silicon carbide single crystal 5 is cooled after growing silicon carbide single crystal 5. The step of growing silicon carbide single crystal 5 includes a step of growing silicon carbide single crystal 5 while maintaining a temperature of a second main surface 2b of base 2 opposite to first main surface 2a to be lower than a temperature of a surface 5a of silicon carbide single crystal 5 facing silicon carbide source material 3. In the step of cooling silicon carbide single crystal 5, silicon carbide single crystal 5 is cooled while maintaining the temperature of second main surface 2b of base 2 to be not less than the temperature of surface 5a of silicon carbide single crystal 5. Accordingly, during the cooling of silicon carbide single crystal 5, it is possible to suppress introduction or propagation of crystal defects to the silicon carbide single crystal.

(2) Preferably in the method for manufacturing the silicon carbide single crystal according to (1), in the step of cooling silicon carbide single crystal 5, in a temperature range in which the temperature of surface 5a of silicon carbide single crystal 5 is not less than 1800° C. and not more than 2000° C., silicon carbide single crystal 5 is cooled while maintaining the temperature of second main surface 2b of base 2 to be not less than the temperature of surface 5a of silicon carbide single crystal 5. In the step of cooling silicon carbide single crystal 5 in the temperature range in which the temperature of surface 5a of silicon carbide single crystal 5 is not less than 1800° C. and not more than 2000° C., atoms of silicon carbide single crystal 5 are facilitated to be moved. Hence, by cooling silicon carbide single crystal 5 in the temperature range while maintaining the temperature of second main surface 2b of base 2 to be not less than the temperature of surface 5a of silicon carbide single crystal 5, it is possible to further suppress introduction or propagation of crystal defects during the cooling.

(3) Preferably in the method for manufacturing the silicon carbide single crystal according to (2), in the step of cooling silicon carbide single crystal 5, in a temperature range in which the temperature of surface 5a of silicon carbide single crystal 5 is not less than 1000° C. and not more than 2000° C., silicon carbide single crystal 5 is cooled while maintaining the temperature of second main surface 2b of base 2 to be not less than the temperature of surface 5a of silicon carbide single crystal 5. Accordingly, also in a temperature range in which the temperature of surface 5a of silicon carbide single crystal 5 is not less than 1000° C. and less than 1800° C., thermal stress in silicon carbide single crystal 5 can be made small. This provides suppression of basal plane dislocation, which is considered to be introduced into silicon carbide single crystal 5 at not less than 1000° C. particularly due to the thermal stress.

(4) Preferably in the method for manufacturing the silicon carbide single crystal according to (3), in the step of cooling silicon carbide single crystal 5, in a temperature range in which the temperature of surface 5a of silicon carbide single crystal 5 is not less than 500° C. and not more than 2000° C., silicon carbide single crystal 5 is cooled while maintaining the temperature of second main surface 2b of base 2 to be not less than the temperature of surface 5a of silicon carbide single crystal 5. Accordingly, also in a temperature range in which the temperature of surface 5a of silicon carbide single crystal 5 is not less than 500° C. and less than 1000° C., thermal stress in silicon carbide single crystal 5 can be made small. This provides suppression of not only crystal defects but also crack or fracture otherwise caused in silicon carbide single crystal 5 due to the thermal stress.

(5) Preferably in the method for manufacturing the silicon carbide single crystal according to any one of (1) to (4), the step of cooling silicon carbide single crystal 5 includes a step of increasing a pressure in accommodation unit 1 before the temperature of second main surface 2b of base 2 becomes not less than the temperature of surface 5a of silicon carbide single crystal 5. This provides suppression of sublimation of grown silicon carbide single crystal 5 when the temperature of surface 5a of silicon carbide single crystal 5 becomes higher than the temperature of surface 3a of silicon carbide source material 3.

(6) Preferably in the method for manufacturing the silicon carbide single crystal according to any one of (1) to (5), in the step of cooling silicon carbide single crystal 5, silicon carbide single crystal 5 is cooled while heating base 2. Accordingly, the temperature of second main surface 2b of base 2 can be maintained to be not less than the temperature of surface 5a of silicon carbide single crystal 5.

(7) Preferably in the method for manufacturing the silicon carbide single crystal according to any one of (1) to (6), in the step of cooling silicon carbide single crystal 5, silicon carbide single crystal 5 is cooled while maintaining a temperature of a bottom portion 1b of accommodation unit 1 to be lower than the temperature of second main surface 2b of base 2. Accordingly, the temperature of second main surface 2b of base 2 can be more securely maintained to be not less than the temperature of surface 5a of silicon carbide single crystal 5, thereby achieving further suppression of introduction or propagation of crystal defects during the cooling.

(8) Preferably in the method for manufacturing the silicon carbide single crystal according to any one of (1) to (7), the step of cooling silicon carbide single crystal 5 includes a step of cooling silicon carbide single crystal 5 while maintaining the temperature of second main surface 2b of base 2 to be not less than the temperature of second main surface 2b of base 2 in the step of growing silicon carbide single crystal 5. Accordingly, the temperature of second main surface 2b of base 2 can be more securely maintained to be not less than the temperature of surface 5a of silicon carbide single crystal 5, thereby achieving further suppression of introduction or propagation of crystal defects during the cooling.

(9) Preferably, the method for manufacturing the silicon carbide single crystal according to any one of (1) to (8) further includes a step of annealing, after the step of growing silicon carbide single crystal 5 and before the step of cooling silicon carbide single crystal 5, silicon carbide single crystal 5 while maintaining a pressure in accommodation unit 1 to be higher than a pressure in the step of growing silicon carbide single crystal 5. This provides further suppression of introduction or propagation of crystal defects into silicon carbide single crystal 5.

### Details of Embodiments

The following describes a configuration of a manufacturing apparatus for a silicon carbide single crystal according to the present disclosure.

As shown in FIG. 1, manufacturing apparatus 10 for the silicon carbide single crystal mainly includes an accommodation unit 1, a base 2, a heat source (not shown), and a thermometer (not shown). Accommodation unit 1 is configured to be capable of accommodating a silicon carbide source material 3 therein. Base 2 is configured to be capable of holding a seed crystal 4 made of silicon carbide single crystal. Base 2 has a cylindrical shape, and has a first main surface 2a and a second main surface 2b opposite to first main surface 2a, for example. Seed crystal 4 is fixed to first main surface 2a of base 2 by an adhesive agent or the like, for example. Base 2 is disposed on the upper portion of accommodation unit 1 to close the opening of accommodation unit 1. Each of accommodation unit 1 and base 2 is made of a material including porous graphite, for example.

The heat source is disposed outside accommodation unit 1 to surround accommodation unit 1, for example. The heat source may be a high-frequency induction-heating type coil or a resistive heating type heater. The heat source may be disposed at a location facing second main surface 2b of base 2. The heat source may be disposed at a location facing bottom portion 1b of accommodation unit 1. The thermometer is a radiation thermometer, for example. The thermometer may be configured to be capable of measuring each of temperatures of second main surface 2b of base 2 and side surface 1a and bottom portion 1b of accommodation unit 1, for example. The thermometer may be configured to be capable of measuring a temperature within accommodation unit 1.

The following describes a method for manufacturing the silicon carbide single crystal according to the present disclosure.

As shown in FIG. 1, silicon carbide source material 3 is provided in accommodation unit 1. Silicon carbide source material 3 is powder of polycrystalline silicon carbide, for example. Seed crystal 4 is fixed to first main surface 2a of base 2 using an adhesive agent, for example. Seed crystal 4 is made of hexagonal silicon carbide single crystal of polytype 4H, for example. The diameter of the surface of seed crystal 4 is, for example, not less than 100 mm and is preferably not less than 150 mm. The surface of seed crystal 4 corresponds to a plane angled off by about 8° or less relative to a {0001} plane, for example. Seed crystal 4 is disposed such that the surface of seed crystal 4 faces surface 3a of silicon carbide source material 3. As described above, silicon carbide source material 3 and seed crystal 4 are prepared, silicon carbide source material 3 being provided in accommodation unit 1, seed crystal 4 being provided to face silicon carbide source material 3, seed crystal 4 being fixed to first main surface 2a of base 2.

Next, silicon carbide source material 3 provided in accommodation unit 1 is heated to a temperature of about not less than 2000° C. and not more than 2400° C., for example. While the temperature of silicon carbide source material 3 is being increased, the pressure of atmospheric gas in accommodation unit 1 is maintained at about 80 kPa, for example. The atmospheric gas includes an inert gas, such as argon gas, helium gas, or nitrogen gas, for example. Next, the pressure of the atmospheric gas in accommodation unit 1 is decreased to 1.7 kPa, for example. Accordingly, silicon carbide source material 3 in accommodation unit 1 starts to sublime and is recrystallized on the surface of seed crystal 4 disposed at the location facing the surface of silicon carbide source material 3, thereby starting to grow silicon carbide single crystal 5 on the surface of seed crystal 4. During the growth of the silicon carbide single crystal, the pressure in accommodation unit 1 is maintained at about not less than 0.5 kPa and not more than 5 kPa for about 10 hours, for example. By sublimating silicon carbide source material 3 as described above, silicon carbide single crystal 5 is grown on seed crystal 4.

As shown in FIG. 2, in the step of growing the silicon carbide single crystal, the temperature of the surface of seed crystal 4 is maintained to be lower than the temperature of surface 3a of silicon carbide source material 3. Specifically, the temperatures of accommodation unit 1 and base 2 are controlled such that the temperature of bottom portion 1b of accommodation unit 1 becomes the highest and the temperature of second main surface 2b of base 2 becomes the lowest in the direction perpendicular to second main surface 2b of base 2. The temperature of bottom portion 1b of accommodation unit 1 is higher than the temperature of the bottom surface of silicon carbide source material 3. The temperature of the bottom surface of silicon carbide source material 3 may be higher than the temperature of surface 3a of silicon carbide source material 3. A temperature gradient between bottom portion 1b of accommodation unit 1 and the bottom surface of silicon carbide source material 3 may be larger than a temperature gradient between the bottom surface and surface 3a of silicon carbide source material 3, The temperature of surface 3a of silicon carbide source material 3 is higher than the temperature of surface 5a of silicon carbide single crystal 5. However, a temperature distribution between surface 3a of silicon carbide source material 3 and surface 5a of silicon carbide single crystal 5 may not be particularly specified. When there is a temperature gradient between surface 3a of silicon carbide source material 3 and surface 5a of silicon carbide single crystal 5, the temperature gradient between the bottom surface and surface 3a of silicon carbide source material 3 may be larger than the temperature gradient between surface 3a of silicon carbide source material 3 and surface Sa of silicon carbide single crystal 5.

As shown in FIG. 2, in the step of growing the silicon carbide single crystal, the temperature of surface 5a of silicon carbide single crystal 5 is higher than the temperature of first main surface 2a of base 2. The temperature distribution between surface 3a of silicon carbide source material 3 and surface 5a of silicon carbide single crystal 5 may not be particularly specified. When there is a temperature gradient between surface 3a of silicon carbide source material 3 and surface 5a of silicon carbide single crystal 5, the temperature gradient between surface 3a of silicon carbide source material 3 and surface 5a of silicon carbide single crystal 5 may be smaller than the temperature gradient between surface 5a of silicon carbide single crystal 5 and first main surface 2a of base 2. The temperature of first main surface 2a of base 2 is higher than the temperature of second main surface 2b of base 2. The temperature gradient between surface 5a of silicon carbide single crystal 5 and first main surface 2a of base 2 may be larger than the temperature gradient between first main surface 2a and second main surface 2b of base 2. As described above, in the step of growing silicon carbide single crystal 5, silicon carbide single crystal 5 is grown with the temperature of second main surface 2b of base 2 being maintained to be lower than the temperature of surface 5a of silicon carbide single crystal 5 facing surface 3a of silicon carbide source material 3.

Next, after completion of the crystal growth of silicon carbide single crystal 5, silicon carbide single crystal 5 is cooled. The step of cooling silicon carbide single crystal 5 includes a step of cooling silicon carbide single crystal 5 while maintaining the temperature of second main surface 2b of base 2 to be not less than the temperature of surface 5a of silicon carbide single crystal 5. Preferably, silicon carbide single crystal 5 is cooled while heating base 2. For example, silicon carbide single crystal 5 is cooled while heating base 2, by turning off the heat source facing side surface 1a of accommodation unit 1 while maintaining, at the on state, the heat source facing second main surface 2b of base 2. Alternatively, by cooling silicon carbide single crystal 5 actively without heating second main surface 2b of base 2, silicon carbide single crystal 5 may be cooled while maintaining the temperature of second main surface 2b of base 2 to be not less than the temperature of surface 5a of silicon carbide single crystal 5.

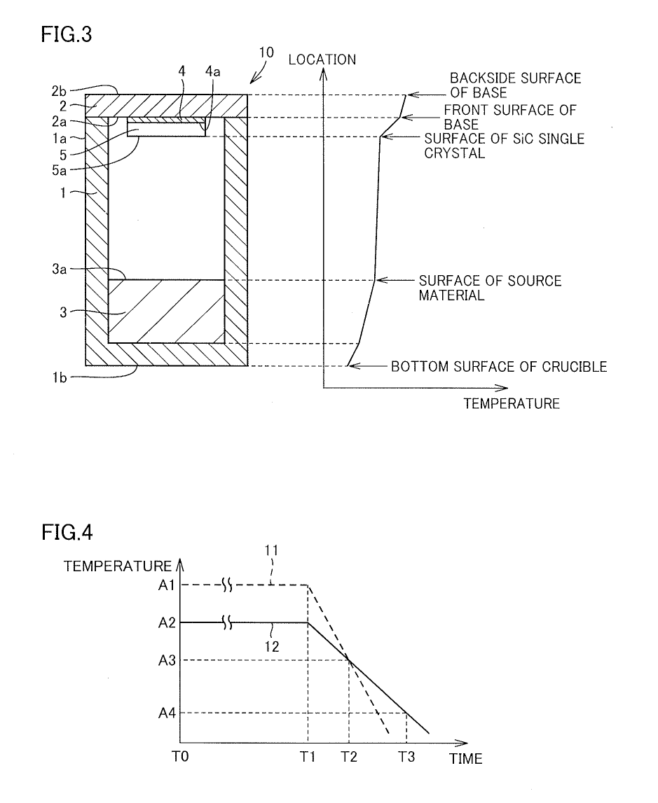

As shown in FIG. 3, in the step of cooling the silicon carbide single crystal, the temperatures of accommodation unit 1 and base 2 are controlled such that the temperature of bottom portion 1b of accommodation unit 1 becomes the lowest and the temperature of second main surface 2h of base 2 becomes the highest in the direction perpendicular to second main surface 2b of base 2. That is, in the step of cooling silicon carbide single crystal 5, silicon carbide single crystal 5 is cooled while maintaining the temperature of bottom portion 1b of accommodation unit 1 to be lower than the temperature of second main surface 2b of base 2. The temperature of bottom portion 1b of accommodation unit 1 is lower than the temperature of the bottom surface of silicon carbide source material 3. The temperature of the bottom surface of silicon carbide source material 3 is lower than the temperature of surface 3a of silicon carbide source material 3. The temperature gradient between bottom portion 1b of accommodation unit 1 and the bottom surface of silicon carbide source material 3 may be larger than the temperature gradient between the bottom surface and surface 3a of silicon carbide source material 3. The temperature of surface 3a of silicon carbide source material 3 may be lower than the temperature of surface 5a of silicon carbide single crystal 5. The temperature distribution between surface 3a of silicon carbide source material 3 and surface 5a of silicon carbide single crystal 5 may not be particularly specified. When there is a temperature gradient between surface 3a of silicon carbide source material 3 and surface 5a of silicon carbide single crystal 5, the temperature gradient between the bottom surface and surface 3a of silicon carbide source material 3 may be larger than the temperature gradient between surface 3a of silicon carbide source material 3 and surface 5a of silicon carbide single crystal 5.

As shown in FIG. 3, in the step of cooling the silicon carbide single crystal, the temperature of surface 5a of silicon carbide single crystal 5 is lower than the temperature of first main surface 2a of base 2. The temperature distribution between surface 3a of silicon carbide source material 3 and surface 5a of silicon carbide single crystal 5 may not be particularly specified. When there is a temperature gradient between surface 3a of silicon carbide source material 3 and surface 5a of silicon carbide single crystal 5, the temperature gradient between surface 3a of silicon carbide source material 3 and surface 5a of silicon carbide single crystal 5 may be smaller than the temperature gradient between surface 5a of silicon carbide single crystal 5 and first main surface 2a of base 2. The temperature of first main surface 2a of base 2 is lower than the temperature of second main surface 2b of base 2. The temperature gradient between surface 5a of silicon carbide single crystal 5 and first main surface 2a of base 2 may be larger than the temperature gradient between first main surface 2a and second main surface 2b of base 2. As described above, the step of cooling silicon carbide single crystal 5 includes a step of cooling silicon carbide single crystal 5 while maintaining the temperature of second main surface 2b of base 2 to be not less than the temperature of surface 5a of silicon carbide single crystal 5 facing surface 3a of silicon carbide source material 3. It should be noted that in a certain temperature range in the step of cooling silicon carbide single crystal 5, the temperature of second main surface 2b of base 2 may become less than surface 5a of silicon carbide single crystal 5.

It should be noted that the temperature in each of the surfaces refers to the temperature of the center of the surface. For example, the temperature of second main surface 2b of base 2 refers to the temperature of the center of second main surface 2b of base 2. Preferably, in the step of cooling silicon carbide single crystal 5, silicon carbide single crystal 5 is cooled while maintaining the average value of the temperature of second main surface 2b of base 2 to be not less than the average value of the temperature of surface 5a of silicon carbide single crystal 5. More preferably, in the step of cooling silicon carbide single crystal 5, silicon carbide single crystal 5 is cooled while maintaining the average value of the temperature of bottom portion 1b of accommodation unit 1 to be lower than the average value of the temperature of second main surface 2b of base 2. It should be noted that the average value of the temperature in each of the surfaces refers to an average value of all the temperatures at a plurality of different locations of measurements in each of the surfaces (for example, five locations including the center). More preferably, in the step of cooling silicon carbide single crystal 5, silicon carbide single crystal 5 is cooled while maintaining the maximum value of the temperatures of the plurality of measurement locations in second main surface 2b of base 2 to be not less than the minimum value of the temperatures of the plurality of measurement locations in surface 5a of silicon carbide single crystal 5. More preferably, in the step of cooling silicon carbide single crystal 5, silicon carbide single crystal 5 is cooled while maintaining the maximum value of the temperatures of the plurality of measurement locations of bottom portion 1b of accommodation unit 1 to be lower than the minimum value of the temperatures of the plurality of measurement locations of second main surface 2b of base 2.

It should be noted that the temperature in each of the surfaces can be measured using a radiation thermometer, for example. When it is difficult to directly measure the temperature of surface 5a of silicon carbide single crystal 5 growing in accommodation unit 1, the temperature of a location 1a1 of side surface 1a of accommodation unit 1 in a plane along the surface of seed crystal 4 that is in contact with silicon carbide single crystal 5 can be used as a reference (see FIG. 1). Because the temperature of location 1a1 is higher than the temperature of the center of surface 5a of silicon carbide single crystal 5, it can be presumed that the temperature of the center of second main surface 2b of base 2 is higher than the temperature of the center of surface 5a of silicon carbide single crystal 5 when the temperature of the center of second main surface 2b of base 2 is higher than the temperature of location 1a1. That is, the condition for cooling can be determined assuming the temperature of location 1a1 as the temperature of the center of surface 5a of silicon carbide single crystal 5.

As shown in FIG. 4 and FIG. 6 to FIG. 9, the following describes a change in temperature of each of surface 5a of silicon carbide single crystal 5 and second main surface 2b of base 2 with time. In FIG. 4 and FIG. 6 to FIG. 9, a broken line 11 represents the temperature of surface 5a of silicon carbide single crystal 5 and a solid line 12 represents the temperature of second main surface 2b of base 2. In FIG. 4 and FIG. 6 to FIG. 9, a period of time T0 to time T1 substantially corresponds to the step of growing the silicon carbide single crystal.

As shown in FIG. 4, in the step of growing the silicon carbide single crystal, the temperature of surface 5a of silicon carbide single crystal 5 is maintained to be higher than the temperature of second main surface 2b of base 2. In the step of growing the silicon carbide single crystal, surface 5a of silicon carbide single crystal 5 has a temperature A1 of, for example, not less than 2100° C. and not more than 2400° C. and second main surface 2b of base 2 has a temperature A2 of, for example, not less than 2000° C. and not more than 2300° C. After time T1, silicon carbide single crystal 5 and base 2 are cooled. Silicon carbide single crystal 5 may be cooled at a cooling rate larger than a cooling rate for base 2. At time T2, the temperature of surface 5a of silicon carbide single crystal 5 becomes equal to the temperature of second main surface 2b of base 2. After time T2, the temperature of second main surface 2b of base 2 is maintained to be not less than the temperature of surface 5a of silicon carbide single crystal 5.

Preferably, in a temperature range in which the temperature of surface 5a of silicon carbide single crystal 5 is not less than 1800° C. and not more than 2000° C., silicon carbide single crystal 5 is cooled while maintaining the temperature of second main surface 2b of base 2 to be not less than the temperature of surface 5a of silicon carbide single crystal 5. For example, in FIG. 4, a temperature A3 is 2000° C. and a temperature A4 is 1800° C. It should be noted that when the temperature of surface 5a of silicon carbide single crystal 5 is higher than 2000° C. and is lower than 1800° C., the temperature of second main surface 2b of base 2 may become lower than the temperature of surface 5a of silicon carbide single crystal 5.

Preferably, in a temperature range in which the temperature of surface 5a of silicon carbide single crystal 5 is not less than 1000° C. and not more than 2000° C., silicon carbide single crystal 5 is cooled while maintaining the temperature of second main surface 2b of base 2 to be not less than the temperature of surface 5a of silicon carbide single crystal 5. More preferably, in a temperature range in which the temperature of surface 5a of silicon carbide single crystal 5 is not less than 500° C. and not more than 2000° C., silicon carbide single crystal 5 is cooled while maintaining the temperature of second main surface 2b of base 2 to be not less than the temperature of surface 5a of silicon carbide single crystal 5.

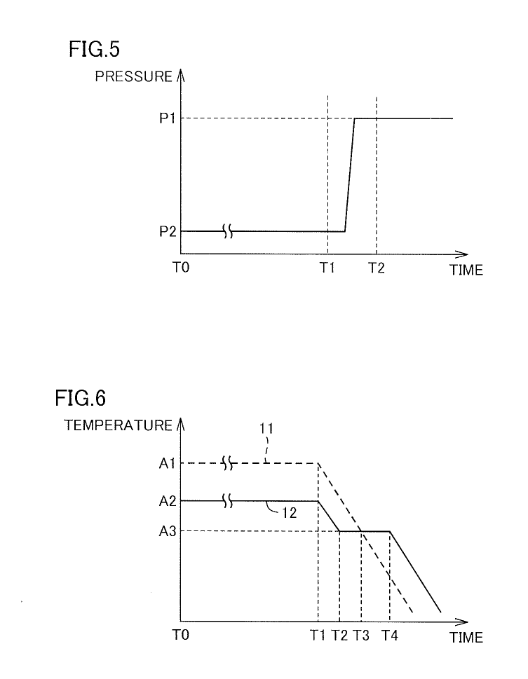

As shown in FIG. 5, the following describes a change of pressure in accommodation unit 1 with time. As shown in FIG. 5, a pressure P2 is, for example, not less than 0.5 kPa and not more than 5 kPa during the period of time T0 to time T1 in which silicon carbide single crystal 5 is substantially grown. At time T1 after substantial completion of the crystal growth of silicon carbide single crystal 5, silicon carbide single crystal 5 starts to be cooled. Preferably, the pressure in accommodation unit 1 is increased after time T1 at which silicon carbide single crystal 5 starts to be cooled and before time T2 at which the temperature of second main surface 2b of base 2 becomes not less than the temperature of surface 5a of silicon carbide single crystal 5. Specifically, a pressure P1 in accommodation unit 1 at time T2 is 30 kPa, for example. For example, the pressure in accommodation unit 1 is increased by introducing an inert gas such as argon into accommodation unit Before starting to cool silicon carbide single crystal 5, the pressure in accommodation unit 1 may be increased to be higher than the pressure for the crystal growth.

As shown in FIG. 6, after passage of a certain period of time after starting to cool silicon carbide single crystal 5, the temperature of silicon carbide single crystal 5 may be maintained for a certain period of time and silicon carbide single crystal 5 may be then cooled again. As shown in FIG. 6, each of silicon carbide single crystal 5 and base 2 is cooled after time T1 at which the crystal growth of silicon carbide single crystal 5 is substantially completed. From time T2 to time T4, second main surface 2b of base 2 is maintained at temperature A3. On the other hand, from time T2 to time T4, the temperature of surface 5a of silicon carbide single crystal 5 is monotonously decreased. At time T3, the temperature of second main surface 2b of base 2 becomes equal to the temperature of surface 5a of silicon carbide single crystal 5. Between time T3 and time T4, the temperature of second main surface 2b of base 2 is maintained to be not less than the temperature of surface 5a of silicon carbide single crystal 5.

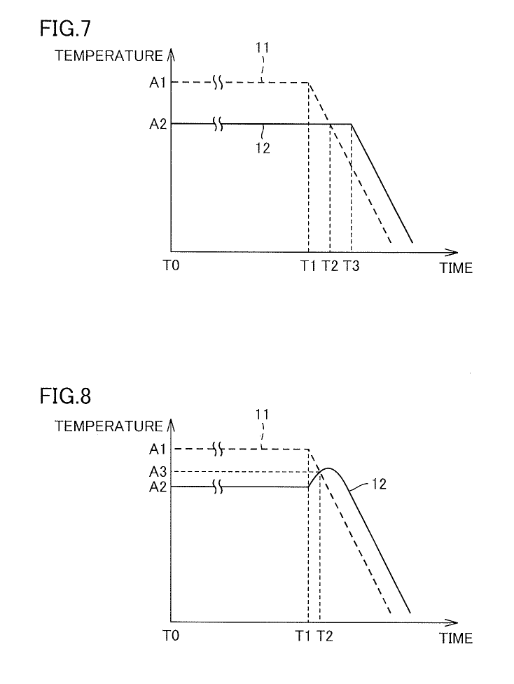

As shown in FIG. 7, in the step of cooling silicon carbide single crystal 5, silicon carbide single crystal 5 may be cooled while maintaining the temperature of second main surface 2b of base 2 to be not less than the temperature of second main surface 2b of base 2 in the step of growing silicon carbide single crystal 5. As shown in FIG. 7, after time T1 at which the crystal growth of silicon carbide single crystal 5 is substantially completed, the temperature of surface 5a of silicon carbide single crystal 5 is decreased monotonously. On the other hand, during a period of time after time T1 till time T3, second main surface 2b of base 2 is maintained at temperature A2 for the crystal growth. At time T2, the temperature of second main surface 2b of base 2 becomes equal to the temperature of surface 5a of silicon carbide single crystal 5. Between time T2 and time T3, the temperature of second main surface 2b of base 2 is maintained to be not less than the temperature of surface 5a of silicon carbide single crystal 5.

As shown in FIG. 8, after time T1 at which the crystal growth of silicon carbide single crystal 5 is completed substantially, base 2 may be heated while cooling silicon carbide single crystal 5. In this case, after time T1, the temperature of surface 5a of silicon carbide single crystal 5 is decreased monotonously. On the other hand, after time T1, the temperature of second main surface 2b of base 2 once becomes higher than the temperature thereof for the crystal growth, and then becomes equal to the temperature of surface 5a of silicon carbide single crystal 5 at time T2. Temperature A3 of second main surface 2b of base 2 at time T2 may be higher than the temperature of second main surface 2b of base 2 in the crystal growth, and may be lower than the temperature of surface 5a of silicon carbide single crystal 5 in the crystal growth. After time T2, the temperature of second main surface 2b of base 2 may be further increased to attain the maximum value, and then may start to be decreased.

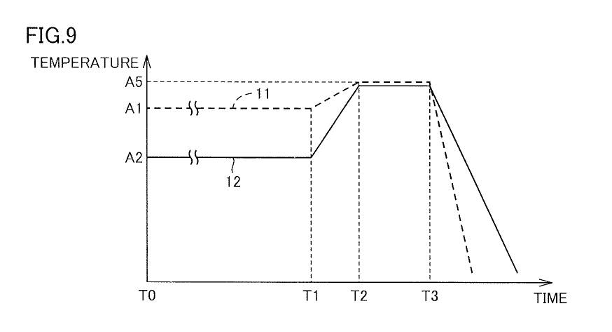

As shown in FIG. 9, a step of annealing silicon carbide single crystal 5 may be performed after the step of growing silicon carbide single crystal 5 and before the step of cooling silicon carbide single crystal 5. For example, a period after time T0 till time T1 corresponds to the step of crystal growth of silicon carbide single crystal 5, a period after time T1 till time T3 corresponds to the step of annealing silicon carbide single crystal 5, and a period after time T3 corresponds to the step of cooling silicon carbide single crystal 5. After time T1 at which the crystal growth of silicon carbide single crystal 5 is completed substantially, silicon carbide single crystal 5 is annealed while maintaining the pressure in accommodation unit 1 to be higher than the pressure in the step of growing silicon carbide single crystal 5. Specifically, after time T1, the temperature of surface 5a of silicon carbide single crystal 5 is increased from temperature A1 to temperature A5 with an inert gas such as argon being in accommodation unit 1. During a period after time T2 till time T3, the temperature of surface 5a of silicon carbide single crystal 5 is maintained at temperature A5. Second main surface 2b of base 2 is maintained at a temperature higher than temperature A1, for example. After time T3, each of silicon carbide single crystal 5 and base 2 is cooled. A difference in temperature between the surface of silicon carbide single crystal 5 and second main surface 2b of base 2 during the crystal growth may be larger than that during the annealing.

Next, the following describes function and effect of the method for manufacturing the silicon carbide single crystal according to the present embodiment.

According to the method for manufacturing the silicon carbide single crystal according to the present embodiment, silicon carbide source material 3 and seed crystal 4 are prepared, silicon carbide source material 3 being provided in accommodation unit 1, seed crystal 4 being provided to face silicon carbide source material 3, seed crystal 4 being fixed to first main surface 2a of base 2. By sublimating silicon carbide source material 3, silicon carbide single crystal 5 is grown on seed crystal 4. After growing silicon carbide single crystal 5, silicon carbide single crystal 5 is cooled. The step of growing silicon carbide single crystal 5 includes the step of growing silicon carbide single crystal 5 while maintaining the temperature of second main surface 2b of base 2 opposite to first main surface 2a to be lower than the temperature of surface 5a of silicon carbide single crystal 5 facing silicon carbide source material 3. In the step of cooling silicon carbide single crystal 5, silicon carbide single crystal 5 is cooled while maintaining the temperature of second main surface 2b of base 2 to be not less than the temperature of surface 5a of silicon carbide single crystal 5. Accordingly, during the cooling of silicon carbide single crystal 5, it is possible to suppress introduction or propagation of crystal defects to silicon carbide single crystal 5.

Moreover, according to the method for manufacturing the silicon carbide single crystal according to the present embodiment, in the step of cooling silicon carbide single crystal 5, in the temperature range in which the temperature of surface 5a of silicon carbide single crystal 5 is not less than 1800° C. and not more than 2000° C., silicon carbide single crystal 5 is cooled while maintaining the temperature of second main surface 2b of base 2 to be not less than the temperature of surface 5a of silicon carbide single crystal 5. In the step of cooling silicon carbide single crystal 5 in the temperature range in which the temperature of surface 5a of silicon carbide single crystal 5 is not less than 1800° C. and not more than 2000° C., atoms of silicon carbide single crystal 5 are facilitated to be moved. Hence, by cooling silicon carbide single crystal 5 in the temperature range while maintaining the temperature of second main surface 2b of base 2 to be not less than the temperature of surface 5a of silicon carbide single crystal 5, it is possible to suppress introduction or propagation of crystal defects during the cooling.

Further, according to the method for manufacturing the silicon carbide single crystal in the present embodiment, in the step of cooling silicon carbide single crystal 5, in the temperature range in which the temperature of surface 5a of silicon carbide single crystal 5 is not less than 1000° C. and not more than 2000° C., silicon carbide single crystal 5 is cooled while maintaining the temperature of second main surface 2b of base 2 to be not less than the temperature of surface 5a of silicon carbide single crystal 5. Accordingly, also in the temperature range in which the temperature of surface 5a of silicon carbide single crystal 5 is not less than 1000° C. and less than 1800° C., thermal stress in silicon carbide single crystal 5 can be made small. This provides suppression of basal plane dislocation, which is considered to be introduced into silicon carbide single crystal 5 at not less than 1000° C. particularly due to the thermal stress. Furthermore, according to the method for manufacturing the silicon carbide single crystal in the present embodiment, in the step of cooling silicon carbide single crystal 5, in the temperature range in which the temperature of surface 5a of silicon carbide single crystal 5 is not less than 500° C. and not more than 2000° C., silicon carbide single crystal 5 is cooled while maintaining the temperature of second main surface 2b of base 2 to be not less than the temperature of surface 5a of silicon carbide single crystal 5. Accordingly, also in the temperature range in which the temperature of surface 5a of silicon carbide single crystal 5 is not less than 500° C. and less than 1000° C., the thermal stress in silicon carbide single crystal 5 can be made small. This provides suppression of not only crystal defects but also crack or fracture otherwise caused in silicon carbide single crystal 5 due to the thermal stress.

Furthermore, according to the method for manufacturing the silicon carbide single crystal in the present embodiment, the step of cooling silicon carbide single crystal 5 includes the step of increasing the pressure in accommodation unit 1 before the temperature of second main surface 2b of base 2 becomes not less than the temperature of surface 5a of silicon carbide single crystal 5. This provides suppression of sublimation of grown silicon carbide single crystal 5 when the temperature of surface 5a of silicon carbide single crystal 5 becomes higher than the temperature of surface 3a of silicon carbide source material 3.

Furthermore, according to the method for manufacturing the silicon carbide single crystal in the present embodiment, in the step of cooling silicon carbide single crystal 5, silicon carbide single crystal 5 is cooled while heating base 2. Accordingly, the temperature of second main surface 2b of base 2 can be maintained to be not less than the temperature of surface 5a of silicon carbide single crystal 5.

Furthermore, according to the method for manufacturing the silicon carbide single crystal in the present embodiment, in the step of cooling silicon carbide single crystal 5, silicon carbide single crystal 5 is cooled while maintaining the temperature of bottom portion 1b of accommodation unit 1 to be lower than the temperature of second main surface 2b of base 2. Accordingly, the temperature of second main surface 2b of base 2 can be more securely maintained to be not less than the temperature of surface 5a of silicon carbide single crystal 5, thereby achieving further suppression of introduction or propagation of crystal defects during the cooling.

Furthermore, according to the method for manufacturing the silicon carbide single crystal in the present embodiment, the step of cooling silicon carbide single crystal 5 includes the step of cooling silicon carbide single crystal 5 while maintaining the temperature of second main surface 2b of base 2 to be not less than the temperature of second main surface 2b of base 2 in the step of growing silicon carbide single crystal 5. Accordingly, the temperature of second main surface 2b of base 2 can be more securely maintained to be not less than the temperature of surface 5a of silicon carbide single crystal 5, thereby achieving further suppression of introduction or propagation of crystal defects during the cooling.

Furthermore, the method for manufacturing the silicon carbide single crystal in the present embodiment further includes the step of annealing, after the step of growing silicon carbide single crystal 5 and before the step of cooling silicon carbide single crystal 5, silicon carbide single crystal 5 while maintaining the pressure in accommodation unit 1 to be higher than the pressure in the step of growing silicon carbide single crystal 5. This provides further suppression of introduction or propagation of crystal defects into silicon carbide single crystal 5.

It should be understood that the embodiments disclosed herein are illustrative and non-restrictive in every respect. The scope of the present invention is defined by the terms of the claims, and is intended to include any modifications within the scope and meaning equivalent to the terms of the claims.

What is claimed is:

1. A method for manufacturing a silicon carbide single crystal comprising steps of:
preparing a silicon carbide source material and a seed crystal, said silicon carbide source material being provided in an accommodation unit, said seed crystal being provided to face said silicon carbide source material, said seed crystal being fixed to a first main surface of a base;
growing a silicon carbide single crystal on said seed crystal by sublimating said silicon carbide source material; and
cooling said silicon carbide single crystal after the step of growing said silicon carbide single crystal,
the step of growing said silicon carbide single crystal including a step of growing said silicon carbide single crystal while maintaining a temperature of a second main surface of said base opposite to said first main surface to be lower than a temperature of a surface of said silicon carbide single crystal facing said silicon carbide source material,
the step of cooling said silicon carbide single crystal including a step of cooling said silicon carbide single crystal while maintaining the temperature of said second main surface of said base to be not less than the temperature of said surface of said silicon carbide single crystal.

2. The method for manufacturing the silicon carbide single crystal according to claim 1, wherein in the step of cooling said silicon carbide single crystal, in a temperature range in which the temperature of said surface of said silicon carbide single crystal is not less than 1800° C. and not more than 2000° C., said silicon carbide single crystal is cooled while maintaining the temperature of said second main surface of said base to be not less than the temperature of said surface of said silicon carbide single crystal.

3. The method for manufacturing the silicon carbide single crystal according to claim 2, wherein in the step of cooling said silicon carbide single crystal, in a temperature range in which the temperature of said surface of said silicon carbide single crystal is not less than 1000° C. and not more than 2000° C., said silicon carbide single crystal is cooled while maintaining the temperature of said second main surface of said base to be not less than the temperature of said surface of said silicon carbide single crystal.

4. The method for manufacturing the silicon carbide single crystal according to claim 3, wherein in the step of cooling said silicon carbide single crystal, in a temperature range in which the temperature of said surface of said silicon carbide single crystal is not less than 500° C. and not more than 2000° C., said silicon carbide single crystal is cooled while maintaining the temperature of said second main surface of said base to be not less than the temperature of said surface of said silicon carbide single crystal.

5. The method for manufacturing the silicon carbide single crystal according to claim 1, wherein the step of cooling said silicon carbide single crystal includes a step of increasing a pressure in said accommodation unit before the temperature of said second main surface of said base becomes not less than the temperature of said surface of said silicon carbide single crystal.

6. The method for manufacturing the silicon carbide single crystal according to claim 1, wherein in the step of cooling said silicon carbide single crystal, said silicon carbide single crystal is cooled while heating said base.

7. The method for manufacturing the silicon carbide single crystal according to claim 1, wherein in the step of cooling said silicon carbide single crystal, said silicon carbide single crystal is cooled while maintaining a temperature of a bottom portion of said accommodation unit to be lower than the temperature of said second main surface of said base.

8. The method for manufacturing the silicon carbide single crystal according to claim 1, wherein the step of cooling said silicon carbide single crystal includes a step of cooling said silicon carbide single crystal while maintaining the temperature of said second main surface of said base to be not less than the temperature of said second main surface of said base in the step of growing said silicon carbide single crystal.

9. The method for manufacturing the silicon carbide single crystal according to claim 1, further comprising a step of annealing, after the step of growing said silicon carbide single crystal and before the step of cooling said silicon carbide single crystal, said silicon carbide single crystal while maintaining a pressure in said accommodation unit to be higher than a pressure in the step of growing said silicon carbide single crystal.
